(19) United States
(12) Patent Application Publication
(10) Pub. No.: US 2011/0186842 A1
(43) Pub. Date: Aug. 4, 2011

(54) Thin film transistor and method of manufacturing the same

(76) Inventors: Sang-Ho Moon, Yongin-City (KR); Kyu-Sik Cho, Yongin-city (KR); Won-Kyu Lee, Yongin-city (KR); Tae-Hoon Yang, Yongin-city (KR); Byoung-Kwon Choo, Yongin-city (KR); Yong-Hwan Park, Yongin-city (KR); Bo-Kyung Choi, Yongin-city (KR); Joon-Hoo Choi, Yongin-city (KR); Yun-Gyu Lee, Yongin-city (KR); Min-Chul Shin, Yongin-city (KR)

(21) Appl. No.: 12/926,861

(22) Filed: Dec. 14, 2010

(30) Foreign Application Priority Data
Dec. 15, 2009 (KR) 10-2009-0124725

(51) Int. Cl. H01L 29/786; H01L 21/336

(52) U.S. Cl. 257/57; 438/158; 257/66; 257/E21.414; 257/E29.291; 257/E29.294

(57) ABSTRACT

A method of manufacturing a thin film transistor and a thin film transistor, the method including sequentially forming a gate insulating layer, an amorphous silicon layer and an insulating layer on an entire top surface of a substrate having a gate electrode; patterning the insulating layer to form an etch stopper; and patterning the amorphous silicon layer to form a semiconductor layer.

### BACKGROUND

1. Field

Embodiments relate to a thin film transistor and a method of manufacturing the same.

2. Description of the Related Art

Recently, there have been attempts to develop thin film transistors that are able to meet demands for manufacture of large-scale and inexpensive active matrix flat-panel display devices and mass production thereof without any deterioration in quality of the active matrix flat-panel display device.

Among thin film transistors, an etch stopper-type thin film transistor may have a stacked structure in which a gate insulating layer, a semiconductor layer, an etch stopper as an insulating layer, a resistive contact layer, and source/drain electrodes are sequentially stacked on a gate electrode.

In an etch stopper-type thin film transistor, a gate electrode may be formed on a substrate, a gate insulating layer may be formed on the gate electrode, and a semiconductor layer may then be deposited on the gate insulating layer and patterned through an etching process. Then, an etch stopper may be deposited on the semiconductor layer and may be patterned through an etching process. Then, a resistive contact layer and source/drain electrodes may be deposited and etched and then patterned after the etching process.

### SUMMARY

Embodiments are directed to a thin film transistor and a method of manufacturing the same, which represents advances over the related art.

Forming the semiconductor layer may include forming a doped amorphous silicon layer on the entire top surface of the substrate and forming a source/drain metal layer on an entire top surface of the doped amorphous silicon layer after forming the etch stopper; and patterning the source/drain metal layer, the doped amorphous silicon layer and the amorphous silicon layer, using a same mask, to form source/drain electrodes, a resistive contact layer and a semiconductor layer, respectively.

The doped amorphous silicon layer and the amorphous silicon layer may be formed at the same time by a single etching process.

Forming the doped amorphous silicon layer and the amorphous silicon layer may include dry-etching.

The doped amorphous silicon layer and the amorphous silicon layer may be etched using the source/drain electrodes as a mask.

The embodiments may also be realized by providing a thin film transistor including a gate electrode on a substrate; a gate insulating layer on an entire top surface of the substrate having the gate electrode thereon; a semiconductor layer on the gate insulating layer, the semiconductor layer overlapping the gate electrode; an etch stopper on the semiconductor layer; a resistive contact layer on the semiconductor layer and the etch stopper; and source/drain electrodes on the resistive contact layer, wherein the source/drain electrodes, the resistive contact layer, and the semiconductor layer have a same etched surface.

An entire area of the source/drain electrodes may overlie the semiconductor layer.

A top edge of the etch stopper may be between a top edge of the gate electrode and a top edge of the semiconductor layer, and a bottom edge of the etch stopper, which is opposite to the top edge of the etch stopper, may be between a bottom edge of the gate electrode and the top edge of the semiconductor layer, as seen from a plan view.

The top and bottom edges of the etch stopper may be spaced a distance of more than about 2 μm apart from the top and bottom edges of the semiconductor layer and may be spaced a distance of more than about 2 μm apart from the top and bottom edges of the gate electrode.

The source/drain electrodes and the resistive contact layer may not be in direct contact with the gate insulating layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a unit pixel in a flat-panel display device including a thin film transistor according to an embodiment;

FIG. 2 illustrates an enlarged plan view of a region of the thin film transistor of FIG. 1;

FIG. 3 illustrates a cross-sectional view of the thin film transistor taken along line II-II of FIG. 1;

FIGS. 4A to 4E illustrate cross-sectional views of stages in a method of manufacturing a thin film transistor according to an embodiment;

FIG. 5 illustrates a graph showing a variation in threshold voltage of a thin film transistor exposed twice to the etching process and including a gate insulating layer and a variation in threshold voltage of a thin film transistor exposed once to the etching process;

FIG. 6 illustrates a graph showing a variation in leakage current of the thin film transistor as shown in FIGS. 4A to 4E;

FIGS. 7A to 7E illustrate cross-sectional views of stages in a method of manufacturing a thin film transistor according to another embodiment; and

FIGS. 8A to 8F illustrate cross-sectional views of stages in a method of manufacturing a thin film transistor according to yet another embodiment.

### DETAILED DESCRIPTION

Korean Patent Application No. 10-2009-0124725, filed on Dec. 15, 2009, in the Korean Intellectual Property Office, and entitled: “Thin Film Transistor and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, the exemplary embodiments of the thin film transistor and the method of manufacturing the same will now be described in detail with reference to the accompanying drawings. Here, i) the shapes, sizes, ratios, angles, numbers, operations of the parts may be varied to some extent from those shown in the accompanying drawings. ii) The directions and positions of the parts in the drawings may be widely varied according to the position of an observer since the drawings are seen from the eyes of the observer. iii) The same parts in different drawings may have the same reference numerals. iv) The terms “include(s),” “including,” “has/have,” “having,” “consist(s) of,” and “consisting of” are intended to mean that the parts may include additional sub-parts unless the term “only” is stated. v) Although the parts are used in the singular in the drawings, they may be interpreted to be read as the plural form. vi) The comparison and positional relationships of the numbers, shapes and sizes and the like are intended to be included within the error range even though they are not described in the forms of “approximately,” “substantially,” etc. vii) Although the terms “after,” “before,” “then,” “and,” “here,” “subsequently” and the like are used herein, they are not used with the meaning of defining their temporal positions. viii) The terms “first,” “second” and the like are selectively, exchangeably or repeatedly used for simple classification, and are not intended to have a restrictive meaning. ix) When the terms “on/over,” “below,” “under,” “beside” and the like are used to explain relationships, unless the term “directly” appears before the terms another element may be interposed between the elements thus described. x) When the parts are listed with the use of the term “or,” they are intended to include the parts used alone and in combinations thereof, but are intended to include the parts used alone when they are listed with the use of the term “either . . . or.” xi) The term “Comparative Example” is used herein for the purpose of simple comparison, but may not necessarily refer to prior art, and may be unknown in the prior art and included within the scope of the present invention.

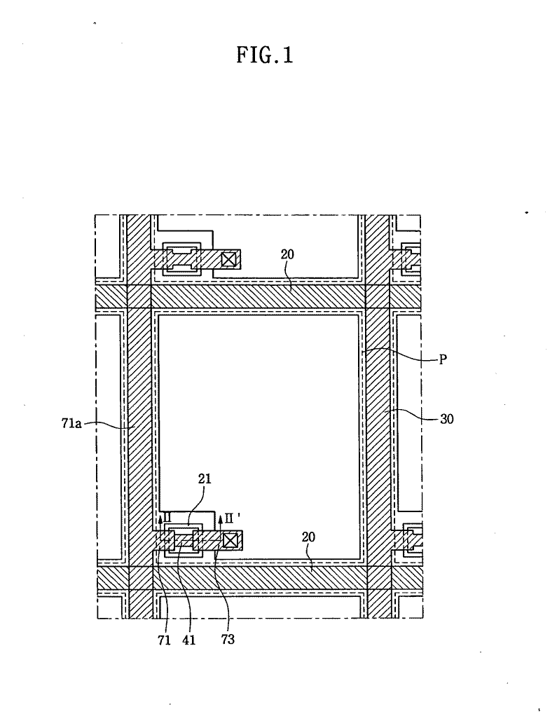

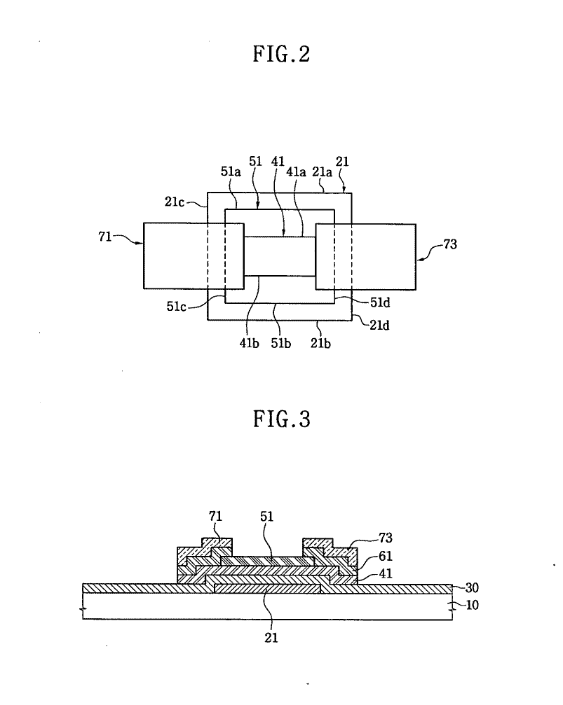

FIG. 1 illustrates a plan view of a unit pixel in a flat-panel display device including a thin film transistor according to an embodiment. FIG. 2 illustrates an enlarged plan view of a region of the thin film transistor T, as shown in FIG. 1. FIG. 3 illustrates a cross-sectional view of the thin film transistor taken along line II-II of FIG. 1.

Referring to FIGS. 1 to 3, a gate interconnection 20 and a gate electrode 21 extending from the gate interconnection 20 may be unidirectionally arranged on a substrate 10. A data interconnection 71a intersecting vertically with the gate interconnection 20, a source electrode 71 extending from the data interconnection 71a, and a drain electrode 73 spaced apart from the source electrode 71 may also be arranged on the substrate 10. A region defined by the intersecting gate interconnection 20 and the data interconnection 70a is called a pixel region, P.

A semiconductor layer 41 made of, e.g., amorphous silicon or polysilicon, an etch stopper 51 as an insulating layer, and a resistive contact layer 61 made of, e.g., doped amorphous silicon, may be stacked between the gate electrode 21 and the source and drain electrodes 71 and 73.

The thin film transistor, T may include the gate electrode 21, the semiconductor layer 41, the etch stopper 51, the resistive contact layer 61, and the source and drain electrodes 71 and 73.

As seen from the plan view of FIG. 2, a top edge 51a of the etch stopper 51 may be arranged between a top edge 21a of the gate electrode 21 and a top edge 41a of the semiconductor layer 41. A bottom edge 51b of the etch stopper 51, which is opposite to the top edge 21a of the etch stopper 51, may be arranged between a bottom edge 21b of the gate electrode 21 and a bottom edge 41b of the semiconductor layer 41.

For example, since the patterns may not be properly arranged due to errors in formation of the patterns, the top and bottom edges 51a and 51b of the etch stopper 51 may be spaced a distance of more than about 2 μm from the top and bottom edges 41a and 41b of the semiconductor layer 41, and may be spaced a distance of more than about 2 μm from the top and bottom edges 21a and 21b of the gate electrode 21, in order to secure the process margin to improve quality of ultimate products.

Also in order to secure the process margin, a left edge 51c and a right edge 51d, which is opposite to the left edge 51c, of the etch stopper 51 may be spaced a distance of more than about 2 μm from left and right edges 21 and 21d of the gate electrode 21.

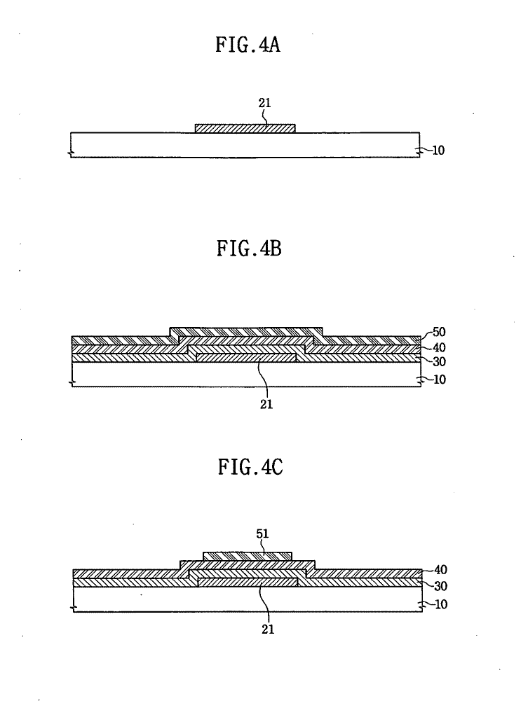

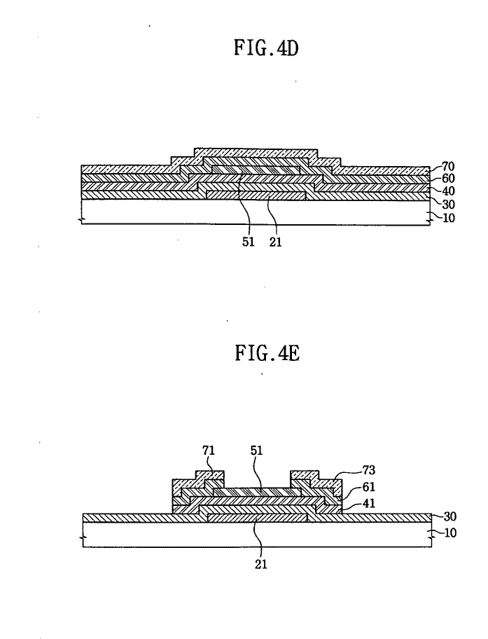

FIGS. 4A to 4E illustrate cross-sectional views of stages in a method of manufacturing the thin film transistor of FIGS. 1 to 3. The method of manufacturing a thin film transistor will now be described in detail with reference to FIGS. 4A to 4E.

Referring to FIG. 4A, a gate metal layer (not illustrated) may be deposited on a substrate 10. Then, the gate metal layer may be patterned to form a gate electrode 21.

For example, the gate metal layer is formed on the substrate 10 through a deposition process such as sputtering. In an implementation, the gate metal layer may be formed of a single layer including at least one of, e.g., aluminum (Al), chromium (Cr), copper (Cu) and molybdenum (Mo), or alloys thereof, or may be formed of a plurality of layers made of combinations thereof. Subsequently, the gate electrode 21 is formed by patterning the gate metal layer through, e.g., photolithographic and etching processes using a first mask.

Referring to FIG. 4B, a gate insulating layer 30, an amorphous silicon layer 40, and an insulating layer 50 may be sequentially deposited on an entire top surface of the substrate 10 having the gate electrode 21 thereon. The sequential deposition may be performed through a deposition process, e.g., plasma-assisted chemical vapor deposition. In an implementation, the gate insulating layer 30 may be made of an inorganic insulating material, e.g., silicon nitride (SiNₓ) or silicon oxide (SiOₓ), and the insulating layer 50 may also be made of, e.g., silicon nitride (SiNₓ) or silicon oxide (SiOₓ).

Referring to FIG. 4C, the insulating layer 50 may be patterned to form an etch stopper 51. Here, the amorphous silicon layer 40 may be on the gate insulating layer 30. Thus, the gate insulating layer 30 may not be affected by the etching process used to form the etch stopper 51.

Referring to FIG. 4D, a doped amorphous silicon layer 60 may be deposited on the entire top surface of the substrate 10 and a source/drain metal layer 70 may be deposited on an entire top surface of the doped amorphous silicon layer 60. In an implementation, the source/drain metal layer 70 may be formed of a single layer including at least one of, e.g., aluminum (Al), chromium (Cr), copper (Cu), and molybdenum (Mo), or alloys thereof, or may be formed of a plurality of layers made of combinations thereof.

Referring to FIG. 4E, the source/drain metal layer 70, the doped amorphous silicon layer 60, and the amorphous silicon layer 40 may be patterned into source/drain electrodes 71 and 73, a resistive contact layer 61, and a semiconductor layer 41, respectively.

For example, the source/drain metal layer 70 may be patterned through wet etching to form source/drain electrodes 71 and 73. The wet etching may be performed using a mask including a photosensitive material, e.g., a single photoresist.

Then, the resistive contact layer 61 and the semiconductor layer 41 may be formed by, e.g., dry-etching the doped amorphous silicon layer 60 and the amorphous silicon layer 40 at the same time using the source/drain electrodes 71 and 73 as a mask.

An entire region or area of the source/drain electrodes 71 and 73 may be arranged on the semiconductor layer 41. The resistive contact layer 61 and the source/drain electrodes 71 and 73 may be spaced apart from the gate insulating layer 30. For example, the resistive contact layer 61 and the source/drain electrodes 71 and 73 may not be in direct contact with the gate insulating layer 30. Here, the resistive contact layer 61 may make an ohmic contact between the source/drain electrodes 71 and 73 and the semiconductor layer 41.

According to the present embodiment, the gate insulating layer 30 may not be exposed twice to the dry etching process, but rather may be exposed only once to the dry etching process. Thus, since the gate insulating layer 30 may not be exposed numerous times to the dry etching process, it is possible to prevent a decrease in thickness of the gate insulating layer 30. Also, since the resistive contact layer 61 may not be in direct contact with the gate insulating layer 30, a layer between the resistive contact layer 61 and the gate insulating layer 30 may be prevented from being loosely formed.

Since the semiconductor layer 41 may be formed using the source/drain electrodes 71 and 73 as the mask, it may not be necessary to form a separate mask to form the semiconductor layer 41. Thus, a decrease in manufacturing costs and a simple manufacturing process may be achieved.

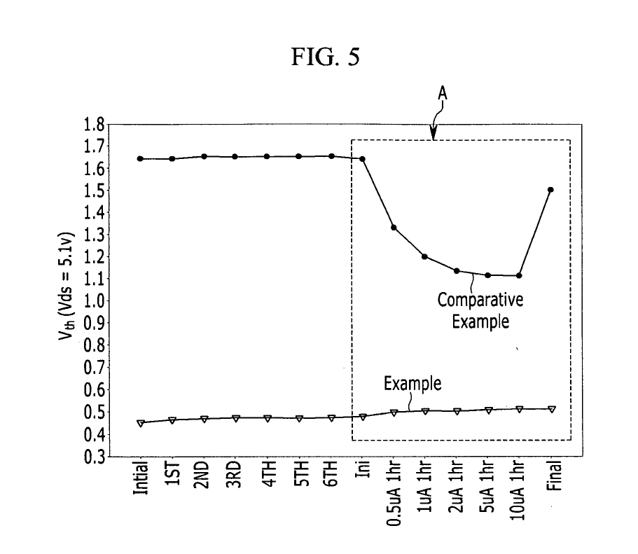

FIG. 5 illustrates a graph showing a variation in threshold voltage of a thin film transistor (Comparative Example) exposed twice to the etching process and including a gate insulating layer, and a variation in threshold voltage of a thin film transistor (Example) formed according to an embodiment. In FIG. 5, the threshold voltage (Vth) of the thin film transistor was measured by applying a constant current for one hour while maintaining a voltage (Vds) between a source electrode and a drain electrode of 5.1V.

In this case, the threshold voltage (Vth) is a voltage at a time point where the thin film transistor is turned on. Here, it is desirable to maintain a constant voltage regardless of the time and current applied.

Referring to region A of FIG. 5, it may be seen that the threshold voltage (Vth) measured according to the bias conditions was sharply changed in the Comparative Example and there was hardly a change in the threshold voltage (Vth) in the Example, in which the thin film transistor was formed according to an embodiment.

Thus, it may be seen that reliability of the thin film transistor may be secured due to a constant threshold voltage may be maintained in the thin film transistor according to the Example.

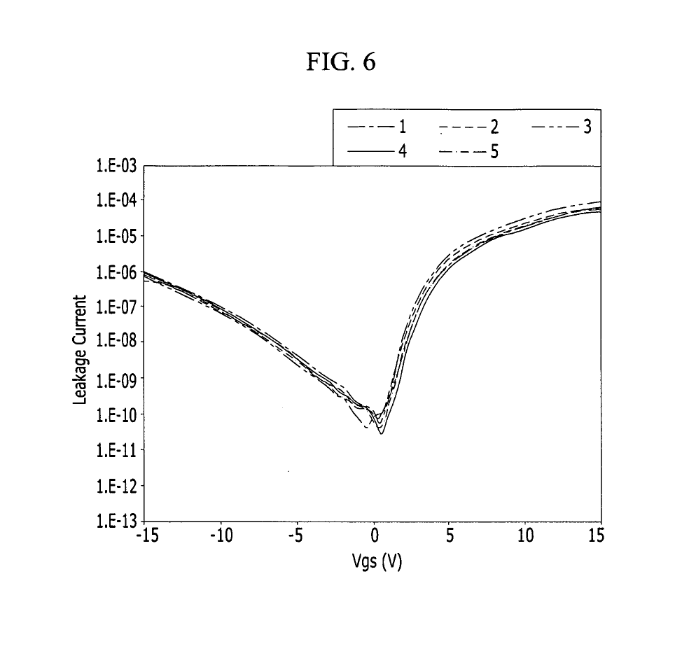

FIG. 6 illustrates a graph showing a variation in leakage current of a thin film transistor according to an Example. In FIG. 6, the leakage currents of five thin film transistors, which were arranged in different pixels on one substrate, were measured, depending on a change in the gate-source voltage (Vgs).

The leakage current of the thin film transistor is an important factor that may determine characteristics of the thin film transistor. The thin film transistor may be considered to exhibit excellent electrical properties when the leakage current drops to approximately 1.E-10A.

Referring to FIG. 6, it may be seen that the leakage currents of all five of the thin film transistors dropped to approximately 1.E-10A. Thus, it may be confirmed that the thin film transistor prepared by the method of an embodiment exhibited excellent leakage current characteristics or electrical properties.

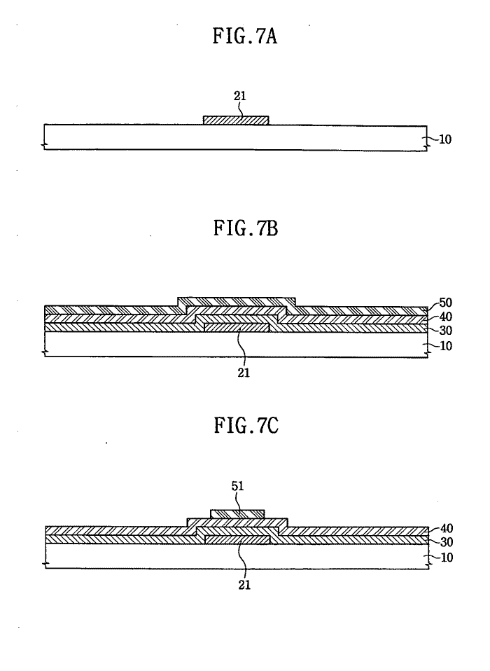

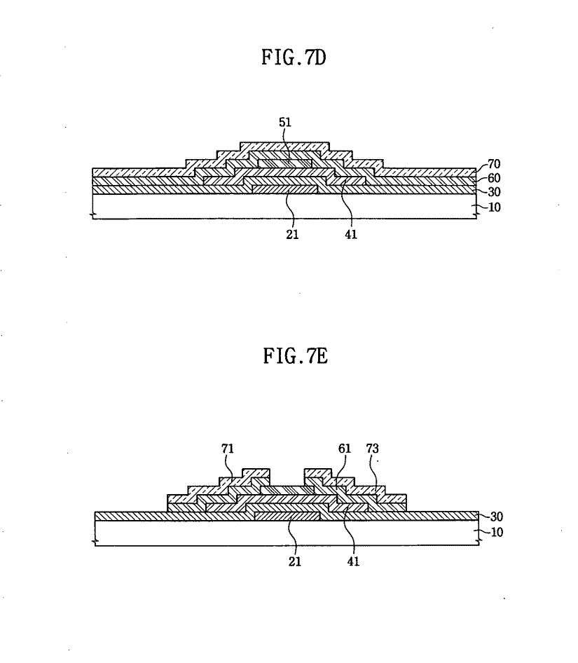

FIGS. 7A to 7E illustrate cross-sectional views of stages in a method of manufacturing a thin film transistor according to another embodiment. The same reference numerals are used for the like parts shown in FIGS. 4A to 4E, and repeated detailed descriptions thereof are omitted for clarity.

Referring to FIG. 7A, a gate metal layer (not shown) may be deposited on the substrate 10 and then patterned to form a gate electrode 21.

Referring to FIGS. 7B and 7C, a gate insulating layer 30, an amorphous silicon layer 40, and an insulating layer 50 may be sequentially deposited on an entire top surface of the substrate 10 having the gate electrode 21 thereon. For example, the sequential deposition may be performed through a deposition process such as plasma-assisted chemical vapor deposition. Then, the insulating layer 50 may be patterned to form an etch stopper 51.

In an implementation, since the amorphous silicon layer 40 may be formed on the gate insulating layer 30, the gate insulating layer 30 may not be affected by the etching process used to form the etch stopper 51.

Referring to FIG. 7D, the amorphous silicon layer 40 may be patterned to form a semiconductor layer 41. Then, a doped amorphous silicon layer 60 may be deposited on the entire top surface of the substrate 10 and a source/drain metal layer 70 may be deposited on an entire top surface of the doped amorphous silicon layer 60.

Referring to FIG. 7E, the doped amorphous silicon layer 60 and the source/drain metal layer 70 may be patterned to form a resistive contact layer 61 and source/drain electrodes 71 and 73, respectively. In an implementation, since the same mask may be used to etch the resistive contact layer 61 and the source/drain electrodes 71 and 73, the resistive contact layer 61 and the source/drain electrodes 71 and 73 may have substantially the same etched surface.

As a result, since the gate insulating layer 30 may be exposed only once to the dry etching process, it is possible to reduce a number of exposures to the dry etching process. Thus, it is possible to prevent an undesirable decrease in thickness of the gate insulating layer 30.

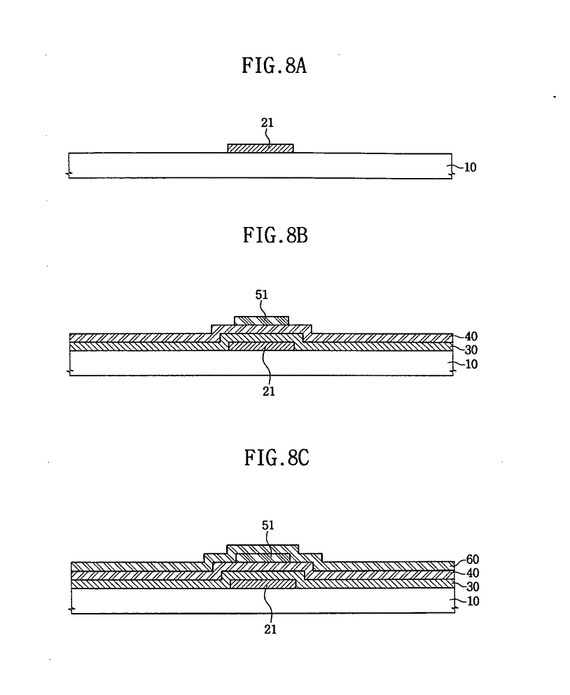

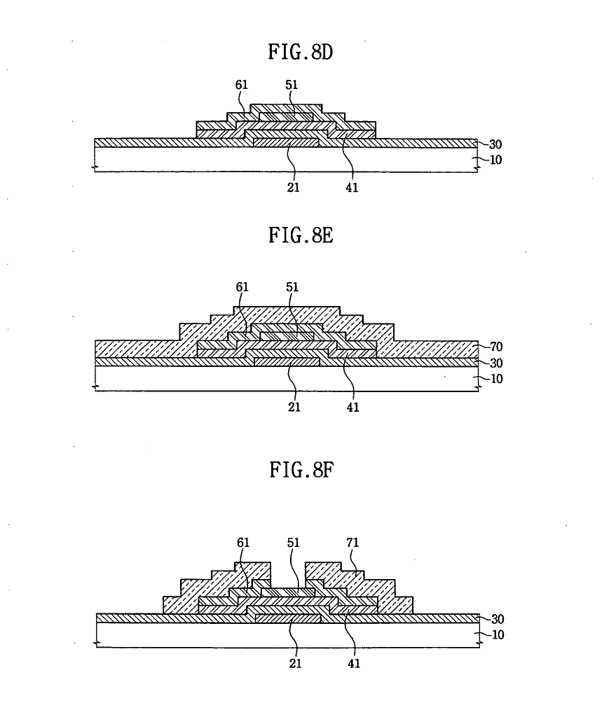

FIGS. 8A to 8F illustrate cross-sectional views of stages in a method of manufacturing a thin film transistor according to yet another embodiment. The same reference numerals are used for the like parts shown in FIGS. 4A to 4E, and repeated detailed descriptions thereof are omitted for clarity.

Referring to FIG. 8A, a gate metal layer (not shown) may be deposited on a substrate 10 and the gate metal layer may then be patterned to form a gate electrode 21.

Referring to FIG. 8B, a gate insulating layer 30, an amorphous silicon layer 40, and an insulating layer 50 may be sequentially deposited on an entire top surface of the substrate 10 having the gate electrode 21 thereon. For example, the sequential deposition may be performed through a deposition process such as plasma-assisted chemical vapor deposition. Subsequently, the insulating layer 50 may be patterned to form an etch stopper 51. In an implementation, since the amorphous silicon layer 40 may be formed on the gate insulating layer 30, the gate insulating layer 30 may not be affected by the etching process used to form the etch stopper 51.

Referring to FIGS. 8C and 8D, a doped amorphous silicon layer 60 may be deposited on the entire top surface of the substrate 10; and a resistive contact layer 61 and a semiconductor layer 41 may be formed at the same time by patterning the doped amorphous silicon layer 60 and the amorphous silicon layer 40. In an implementation, since the semiconductor layer 41 and the resistive contact layer 61 may be etched by the same mask process, the semiconductor layer 41 and the resistive contact layer 61 may have substantially the same etched surface.

Referring to FIGS. 8E and 8F, a source/drain metal layer 70 may be deposited on the entire top surface of the substrate 10; and the source/drain metal layer 70 may then be patterned to form source/drain electrodes 71 and 73; and the resistive contact layer 61 on the etch stopper 51 may be partially etched to electrically disconnect the resistive contact layer 61, which may be arranged below the source/drain electrodes 71 and 73.

As a result, since the gate insulating layer 30 may be exposed only once to the dry etching process, it is possible to reduce a number of exposures to the dry etching process, thus preventing a decrease in thickness of the gate insulating layer 30.

When the etch stopper-type thin film transistor is manufactured using the manufacturing method of an embodiment, exposure of the gate insulating layer during the respective steps of etching the semiconductor layer and etching the etch stopper may be prevented.

According to the embodiments, the semiconductor layer may be formed after the formation of the etch stopper. Accordingly, since the gate insulating layer 30 may be exposed only once to the dry etching process, it is possible to reduce the number of exposures to the dry etching process, which may help prevent an undesirable decrease in thickness of the gate insulating layer 30. By the same token, the method of manufacturing a thin film transistor according to the embodiments may be useful in preventing a decrease in thickness of a gate insulating layer, since it is possible to reduce the number of exposures of the gate insulating layer to a dry etching process.

Also, the method of manufacturing the thin film transistor may be useful in preventing a layer from being loosely formed between a resistive contact layer and a gate insulating layer, since the resistive contact layer may not be in direct contact with the gate insulating layer.

In addition, the thin film transistor may be useful in decreasing manufacturing costs and simplifying a manufacturing process by reducing the procedures in the process of forming a semiconductor layer.

Furthermore, the thin film transistor may be useful in ensuring reliability of the thin film transistor, since a threshold voltage of the thin film transistor may be maintained to a constant level.

Therefore, a thin film transistor of an embodiment may be capable of improving quality of ultimate products, saving on manufacturing costs, and improving stability.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of manufacturing a thin film transistor, the method comprising:
sequentially forming a gate insulating layer, an amorphous silicon layer and an insulating layer on an entire top surface of a substrate having a gate electrode;
patterning the insulating layer to form an etch stopper; and
patterning the amorphous silicon layer to form a semiconductor layer.

2. The method as claimed in claim 1, further comprising:
forming a doped amorphous silicon layer on the entire top surface of the substrate layer after forming the semiconductor layer;
forming a source/drain metal layer on an entire top surface of the doped amorphous silicon layer; and
patterning the doped amorphous silicon layer and the source/drain metal layer using a same mask to form a resistive contact layer and source/drain electrodes.

3. The method as claimed in claim 1, wherein forming the semiconductor layer includes:
forming a doped amorphous silicon layer on the entire top surface of the substrate after forming the etch stopper; and
patterning the doped amorphous silicon and the amorphous silicon layer, using a same mask, to form a resistive contact layer and the semiconductor layer.

4. The method as claimed in claim 3, further comprising:
forming a source/drain metal layer on the entire top surface of the substrate after forming the resistive contact layer and the semiconductor layer; and
patterning the source/drain metal layer to form source/drain electrodes.

5. The method as claimed in claim 3, wherein the doped amorphous silicon layer and the amorphous silicon layer are formed at the same time by a single etching process.

6. The method as claimed in claim 3, wherein forming the doped amorphous silicon layer and the amorphous silicon layer includes dry-etching.

7. The method as claimed in claim 1, wherein forming the semiconductor layer includes:
forming a doped amorphous silicon layer on the entire top surface of the substrate and forming a source/drain metal layer on an entire top surface of the doped amorphous silicon layer after forming the etch stopper; and
patterning the source/drain metal layer, the doped amorphous silicon layer and the amorphous silicon layer, using a same mask, to form source/drain electrodes, a resistive contact layer and a semiconductor layer, respectively.

8. The method as claimed in claim 7, wherein the doped amorphous silicon layer and the amorphous silicon layer are formed at the same time by a single etching process.

9. The method as claimed in claim 7, wherein forming the doped amorphous silicon layer and the amorphous silicon layer includes dry-etching.

10. The method as claimed in claim 7, wherein the doped amorphous silicon layer and the amorphous silicon layer are etched using the source/drain electrodes as a mask.

11. A thin film transistor, comprising:
a gate electrode on a substrate;
a gate insulating layer on an entire top surface of the substrate having the gate electrode thereon;
a semiconductor layer on the gate insulating layer, the semiconductor layer overlapping the gate electrode;
an etch stopper on the semiconductor layer;
a resistive contact layer on the semiconductor layer and the etch stopper; and
source/drain electrodes on the resistive contact layer,
wherein the source/drain electrodes, the resistive contact layer, and the semiconductor layer have a same etched surface.

12. The thin film transistor as claimed in claim 11, wherein an entire area of the source/drain electrodes overlies the semiconductor layer.

13. The thin film transistor as claimed in claim 11, wherein:
a top edge of the etch stopper is between a top edge of the gate electrode and a top edge of the semiconductor layer, and
a bottom edge of the etch stopper, which is opposite to the top edge of the etch stopper, is between a bottom edge of the gate electrode and the top edge of the semiconductor layer, as seen from a plan view.

14. The thin film transistor as claimed in claim 13, wherein the top and bottom edges of the etch stopper are spaced a distance of more than about 2 μm apart from the top and bottom edges of the semiconductor layer and are spaced a distance of more than about 2 μm apart from the top and bottom edges of the gate electrode.

15. The thin film transistor as claimed in claim 11, wherein the source/drain electrodes and the resistive contact layer are not in direct contact with the gate insulating layer.
